(19) United States
(12) Patent Application Publication
(10) Pub. No.: US 2015/0226770 A1
(43) Pub. Date: Aug. 13, 2015

(54) METHOD OF MONITORING AN INDUCTIVE-HEATING APPARATUS

(71) Applicant: Harry KROETZ, Freudenstadt (DE)

(72) Inventor: Harry KROETZ, Freudenstadt (DE)

(21) Appl. No.: 14/620,249

(22) Filed: Feb. 12, 2015

(30) Foreign Application Priority Data
Feb. 12, 2014 (DE) 102014001935.7

(51) Int. Cl. G01R 19/00; H05B 6/02

(52) U.S. Cl. CPC G01R 19/0084; H05B 6/02

(57) ABSTRACT

A device for inductively heating a workpiece has an inductive load path formed by an induction coil juxtaposed with the workpiece and an AC voltage applied across the induction coil and dropping during heating. According to the method the level of the AC voltage is determined. From this determination a voltage-time area over the duration of the heating process is calculated. The determined voltage-time area is then compared to a previously established reference area.

### FIELD OF THE INVENTION

The present invention relates to a method of monitoring an inductive-heating apparatus, more particularly such an apparatus having an induction coil.

### BACKGROUND OF THE INVENTION

It is known, for example, to harden a normally metal workpiece by inductive heating via a load path formed by an induction coil to which is applied an alternating-current (AC) voltage that drops across the induction coil during heating.

### BACKGROUND OF THE INVENTION

Such an inductive heater is known from DE 2 322 720. The amount of heat supplied to the hardening plant is ascertained as electric energy by applying voltages proportional to the induction voltage and the induction current to a multiplier. Since the supplied power varies during the heating phase, it is integrated over the heating time. For this purpose, the output of the multiplier is connected to the input of an integrator. Determinations of the hardening temperature, heating intensity or efficiency of the inductor, among other things, can be inferred from the output value of the circuit arrangement.

One disadvantage of controlled hardening systems is that certain faults, such as in the oscillating circuit of the AC generator, cannot be detected because they are compensated for by the control unit.

### OBJECTS OF THE INVENTION

It is therefore an object of the present invention to provide an improved method of monitoring an inductive-heating apparatus.

Another object is the provision of such an improved method of monitoring an inductive-heating apparatus that overcomes the above-given disadvantages, in particular that does not have the disadvantages of the prior art.

### SUMMARY OF THE INVENTION

A device for inductively heating a workpiece has an inductive load path formed by an induction coil juxtaposed with the workpiece and an AC voltage applied across the induction coil and dropping during heating. According to the method the level of the AC voltage is determined. From this determination a voltage-time area over the duration of the heating process is calculated. The determined voltage-time area is then compared to a previously established reference area.

One advantageous aspect of the invention is to measure the apparent voltage dropping across the induction coil in devices for inductive heating, integrate the same over the heating time, and create a corresponding voltage-time area. The magnetic flux of a conductor loop depends only on the applied voltage-time area, and coupling to the component to be heated takes place via this conductor loop. Depending on the heating state of the component, the system formed by the induction coil and component represents a substantially loaded transformer. A comparison to previously ascertained reference values of the voltage-time area allows conclusions, among other things, of the induction coil geometry, the magnetic coupling between the induction coil and the component to be heated, or the frequency and amplitude of the induction coil current. This method is also used to detect faults on the generator side.

### BRIEF DESCRIPTION OF THE DRAWING

The above and other objects, features, and advantages will become more readily apparent from the following description, reference being made to the accompanying drawing in which:

FIG. 1 is a diagram of the load path of a device for inductively heating workpieces;

FIG. 2a is a diagram a voltage-time area with a sinusoidal voltage curve;

FIG. 2b is a diagram of a voltage-time area over the mean value of the amount of the AC voltage; and

FIGS. 3a-3c are diagrams of a medium-frequency voltage with superimposed high-frequency voltage with associated voltage-time areas.

### SPECIFIC DESCRIPTION OF THE INVENTION

As seen in FIG. 1 a workpiece W is heated inductively by the induction coil I. The induction coil I is connected to an unillustrated generator. The induction coil I has a process resistor that is influenced by the workpiece W. During inductive heating, the voltage Uₛ drops across the process resistor. This voltage changes, for example, when the material or the temperature of the workpiece W, the geometry of the induction coil I, the magnetic coupling between the induction coil I and the workpiece W, or the frequency or amplitude of the current changes. At the same time, faulty behavior of the generator, such as in the oscillating circuit or inverter, is also detected.

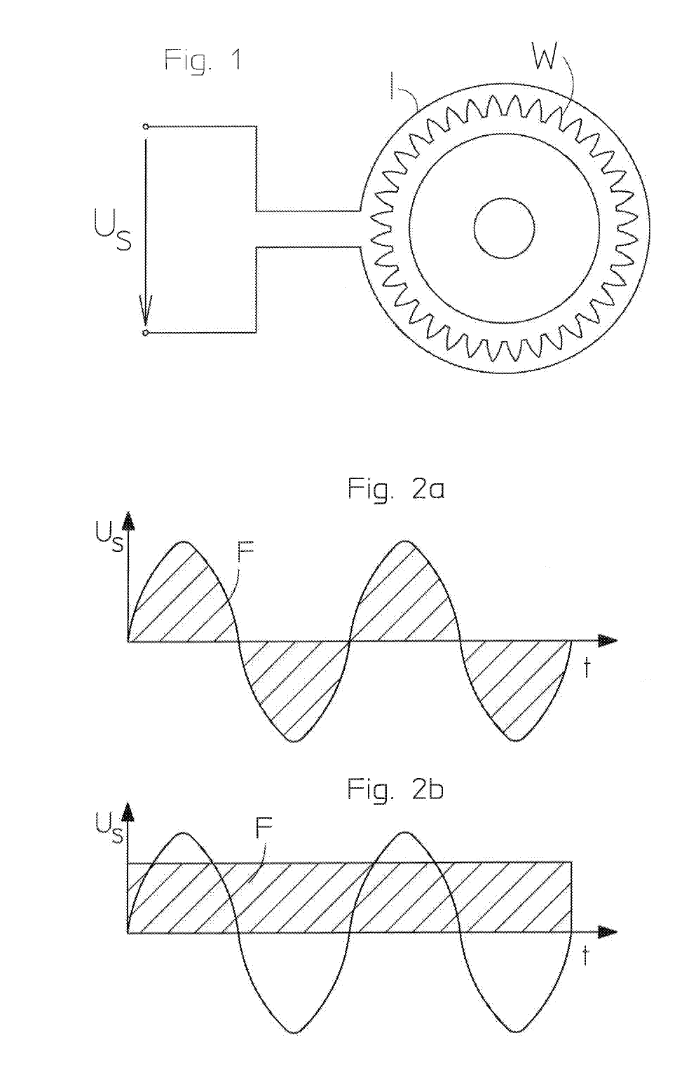

FIG. 2a shows the voltage-time area F for a sinusoidal AC voltage. Comparison of the voltage-time F to previously ascertained reference values provides information about whether the heating process has been successfully completed.

So as to determine the voltage curve, the AC voltage can be sampled. This process is complex, notably at high frequencies of 300 kHz, for example, because the sampling rate must be at least twice as high as the highest frequency component of the AC voltage signal.

An advantageous embodiment is apparent from FIG. 2b. There, a mean value was calculated from the rectified AC voltage and used to determine the voltage-time area F. Any arbitrary mathematical mean value, such as the geometric mean value, arithmetic mean or root mean square, can be used.

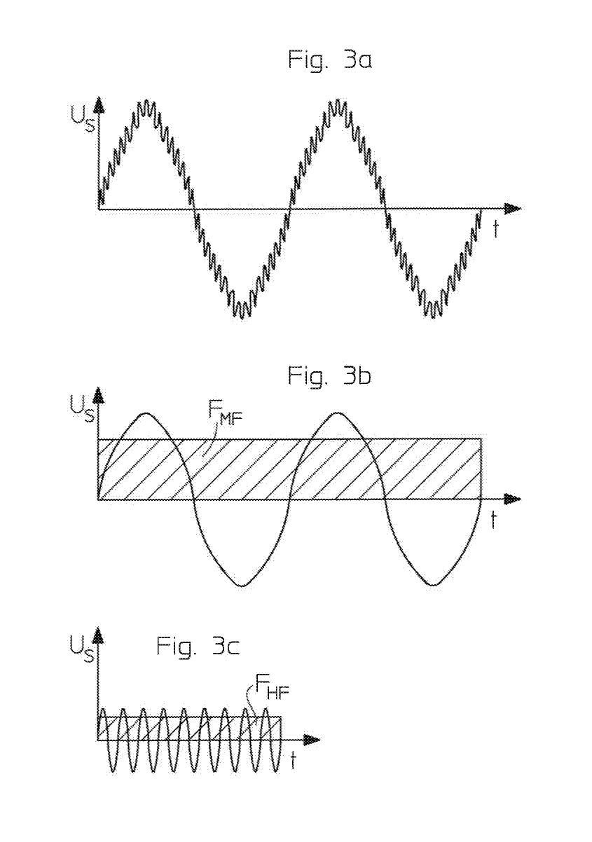

FIG. 3a shows a medium-frequency voltage on which a high-frequency voltage is superimposed. So as to obtain voltage-time areas, the voltage is particularly advantageously divided into a medium-frequency part and a high-frequency part.

According to FIG. 3b, a voltage-time area F_{MF} is determined for the medium-frequency part, and a voltage-time area F_{HF} (FIG. 3c) is determined for the high-frequency part. If deviations from the reference values exist, the method according to the invention even provides information as to whether the irregularities are caused by the medium-frequency or the high-frequency part of the plant.

In addition to hardening devices, the method can also be employed in other systems having inductive heating, such as brazing systems.

I claim:

1. A method of monitoring a device for inductively heating a workpiece, the device having an inductive load path formed by an induction coil juxtaposed with the workpiece and an AC voltage applied across the induction coil and dropping during heating, the method comprising the steps of
determining the AC voltage;
determining a voltage-time area over the duration of the heating process; and
comparing the determined voltage-time area to a previously established reference area.

2. The method defined in claim 1, wherein the AC voltage is sampled at a sampling rate at least twice as high as the highest frequency component of the AC voltage signal.

3. The method defined in claim 1, wherein the voltage-time area is obtained with the help of mean values that are continuously calculated from the level of the AC voltage.

4. The method defined in claim 1, further comprising the steps of:
superimposing a high-frequency voltage on a medium-frequency voltage;
dividing the voltage into a medium-frequency part and a high-frequency part; and
determining a voltage-time area for the medium-frequency part and a voltage-time area is determined for the high-frequency part.
